(19) United States
(12) Patent Application Publication
(10) Pub. No.: US 2012/0119318 A1
(43) Pub. Date: May 17, 2012

(54) SEMICONDUCTOR DEVICE WITH LATERAL ELEMENT

(75) Inventors: Norihito TOKURA, Okazaki-city (JP); Takao Yamamoto, Nukata-gun (JP); Hisato Kato, Nagoya-city (JP); Kouji Senda, Nishikamo-gun (JP); Akio Nakagawa, Chigasaki-city (JP)

(73) Assignee: DENSO CORPORATION, Kariya-city (JP)

(21) Appl. No.: 13/295,236

(22) Filed: Nov. 14, 2011

(30) Foreign Application Priority Data
Nov. 15, 2010 (JP) 2010-255089
Nov. 10, 2011 (JP) 2011-246104

(51) Int. Cl. H01L 29/06

(52) U.S. Cl. 257/489; 257/E29.009

(57) ABSTRACT

In a semiconductor device in which a first electrode and a second electrode are disposed on a surface of a first conductivity-type semiconductor layer of a semiconductor substrate and a lateral element is formed to cause an electric current between the first electrode and the second electrode, a scroll-shaped resistive field plate is disposed on the semiconductor layer across an insulation film. The resistive field plate extends toward the second electrode while surrounding a periphery of the first electrode in a scroll shape. A resistance value of a total resistance of the resistive field plate is in a range between 90 kΩ and 90 MΩ.

### CROSS REFERENCE TO RELATED APPLICATION

This application is based on Japanese Patent Applications No. 2010-255030 filed on Nov. 15, 2010 and No. 2011-246104 filed on Nov. 10, 2011, the disclosure of which are incorporated herein by reference.

### FIELD OF THE INVENTION

The present invention relates to a semiconductor device having a lateral element such as a lateral diode and a lateral insulated gate bipolar transistor (hereinafter referred to as the lateral IGBT), and is, for example, suitably used to a semiconductor device having a lateral diode or a lateral IGBT formed in a SOI (Silicon on insulator) substrate.

### BACKGROUND OF THE INVENTION

Conventionally, there has been a scroll-shaped resistive field plate (hereinafter referred to as the SRFP (Scroll-shaped Field Plate)) as an electric field reduction technology (see, for example, documents 1 and 2). The SRFP has been used in high voltage lateral diode, lateral IGBT, and lateral power MOSFET. It is appreciated that the SRFP withstands a desirable voltage when used under direct current and low-speed switching conditions (see document 3).

<Document 1> Patent Publication No. 3207615

<Document 2> Patent Application Publication No. H04-332173

<Document 3> K. Endo et al,, “A 500V 1A 1-Chip Inverter IC with a New Electric Field Reduction Structure”, Proceeding of the 6th International Symposium on Power Semiconductor Devices & ICs, pp. 379-383 (June 1994)

However, when the lateral power element employing the SRFP is switched at high speed, the electric field reduction by the SRFP will be uneven, resulting in avalanche breakdown and a decrease in transitional withstanding voltage. Thus, there are possibilities of an increase in switching loss and an occurrence of damage to the element. As such, if a micro inverter is made using a lateral power element in which the SRFP having the structure described in the documents 1, 2 or the like is employed, it will be difficult to satisfy requirements of the micro inverter such as high speed operation, high efficiency and low loss.

### SUMMARY OF THE INVENTION

The present invention is made in view of the aforementioned matter, and it is an object to provide a semiconductor device having a lateral element that is capable of restricting the avalanche breakdown and reducing the switching loss and damage to the element, even in a high speed switching operation.

According to an aspect, a semiconductor device includes a semiconductor substrate having a first conductivity-type semiconductor layer, and a first electrode and a second electrode disposed on the surface of the semiconductor layer. A lateral element is formed to generate an electric current between the first electrode and a second electrode. The semiconductor further includes a scroll-shaped resistive field plate disposed on the semiconductor substrate across an insulating film. The resistive field plate extends toward the second electrode while surrounding a periphery of the first electrode in a scroll shape. A resistance value of a total resistance of the resistive field plate is in a range between 90 kΩ and 90 MΩ.

In such a configuration, since the resistance value of the total resistance of the SRFP is set in the range between 90 kΩ and 90 MΩ, it is less likely that the amount of decrease in an electric current at a second peak of peaks where the amount of electric current largely reduces at a time of turning on will be increased. Therefore, even if the semiconductor device is operated at high speed, avalanche breakdown is restricted, and switching loss of the lateral element and damage to the lateral element can be reduced.

For example, when the insulation film has a thickness of 200 nm to 1000 nm, the above described advantageous effect is achieved.

For example, when the thickness of the insulation film is 0.42 μm, the resistance value of the total resistance of the SRFP is set to a range between 270 kΩ and 9 MΩ. Also, when the thickness of the insulation film is 0.42 μm, the resistance value of the total resistance of the SRFP is set to a range between 270 kΩ and 2.7 MΩ. By setting the resistance value of the total resistance of the SRFP in such manners, the increase in the decrease amount of the electric current at the second peak can be restricted.

For example, a resistance value per unit length of the SRFP is constant with respect to a longitudinal direction of the SRFP. Alternatively, the resistance value per unit length of the SRFP varies with respect to the longitudinal direction of the SRFP.

According to a second aspect, a semiconductor device includes a semiconductor substrate having a first conductivity-type semiconductor layer, and a first electrode and a second electrode disposed on the surface of the semiconductor layer. A lateral element is formed to generate an electric current between the first electrode and a second electrode. The semiconductor further includes a scroll-shaped resistive field plate that extends toward the second electrode while surrounding a periphery of the first electrode in a scroll shape. A resistance value per unit length of the resistive field plate increases from the first electrode toward the second electrode.

The electric field concentration at the SRFP adjacent to the second electrode is caused because it is difficult to follow a change in voltage at a time of switching at a position away from the changing point due to a time constant, though the portion adjacent to the changing point can immediately follow the change in voltage. Therefore, by reducing the resistance value per unit length toward the second electrode, the portion away from the changing point can follow the change in voltage at the time of switching. As such, the avalanche breakdown is restricted, and the switching loss of the lateral element and the damage to the lateral element can be reduced.

### BRIEF DESCRIPTION OF THE DRAWINGS

Other objects, features and advantages of the present invention will become more apparent from the following detailed description made with reference to the accompanying drawings, in which like parts are designated by like reference numbers and in which:

FIG. 1 is a circuit diagram of an inverter 1 in which a semiconductor device having a lateral element is employed according to a first embodiment of the present invention;

FIG. 2 is a diagram illustrating a cross-sectional structure of a lateral free wheel diode (hereinafter referred to as the lateral FWD) of the semiconductor device according to the first embodiment;

FIG. 3 is a diagram illustrating an upper layout of one cell of the lateral FWD shown in FIG. 2;

FIG. 4 is a diagram illustrating a cross-sectional structure of the lateral IGBT of the semiconductor device;

FIG. 5 is a diagram illustrating an upper layout of one cell of the lateral IGBT shown in FIG. 4;

FIG. 6 is a circuit diagram illustrating a recovery characteristic evaluation circuit using the lateral FWD and the lateral IGBT;

FIG. 7 is a diagram illustrating a time chart of a respective part in the recovery characteristic evaluation circuit of FIG. 6;

FIG. 8 is a diagram illustrating a cross-sectional view of an evaluation model of the lateral FWD;

FIG. 9 is a diagram illustrating waveforms of an anode voltage Vₐₖ and anode current I_{A} at the time of recovery;

FIG. 10 is a diagram illustrating equipotential distribution above an n⁻-type drift layer in the cross-section shown in FIG. 8, at a second peak;

FIG. 11A is a diagram illustrating an impact ionization rate above the n⁻-type drift layer in the cross-section shown in FIG. 8, at the second peak;

FIG. 11B is a diagram illustrating an enlarged view of an area adjacent to an anode in FIG. 11A;

FIG. 12 is a diagram illustrating a time change in potential of each of ten field plates;

FIG. 13 is a diagram illustrating recovery waveforms when a resistance value of a resistance r provided by the field plate is reduced;

FIG. 14 is a diagram illustrating a time change in potential of each of the ten field plates when the resistance value of the resistance r is 100 kΩ;

FIGS. 15A through FIG. 15C are diagrams illustrating equipotential distribution and impact ionization rate distribution when the resistance value of the resistance r is varied;

FIG. 16 is a diagram illustrating the amount of decrease in anode current I_{A} at the second peak relative to a total resistance R of the SRFP when a rate of decrease di/dt of the initial anode current I_{A} at the time of recovery is varied;

FIG. 17A through 17C are diagrams illustrating a relationship between the resistance value of the total resistance R of the SRFP and the amount of decrease in the anode current I_{A} at the second peak with regard to different thicknesses of a LOCOS oxide film;

FIG. 17D is a diagram in which FIG. 17A through 17C are included together;

FIG. 18 is a diagram illustrating an enlarged view of a part of a SRFP of a lateral FWD or a lateral IGBT, when viewed from the top, according to a second embodiment of the present invention;

FIG. 19 is a diagram illustrating a cross-sectional structure of an n-channel lateral IGBT according to a third embodiment of the present invention;

FIG. 20 is a diagram illustrating a cross-sectional structure of an n-channel lateral IGBT according to a fourth embodiment of the present invention;

FIG. 21A and FIG. 21B are diagrams illustrating an enlarged view of a part of a SRFP of a lateral FWD or a lateral IGBT according to other embodiments; and

FIG. 21C and FIG. 21D are diagrams illustrating an enlarged cross-section of a part of a SRFP of a lateral FWD or a lateral IGBT according to other embodiments.

### DETAILED DESCRIPTION OF EXEMPLARY EMBODIMENTS

Hereinafter, exemplary embodiments of the present invention will be described with reference to the drawings. The same or equivalent parts are designated with the same reference numbers throughout the exemplary embodiments.

### First Embodiment

A first embodiment of the present invention will be described. In the present embodiment, an inverter for driving a three-phase motor will be described as an example of a semiconductor device having a lateral element.

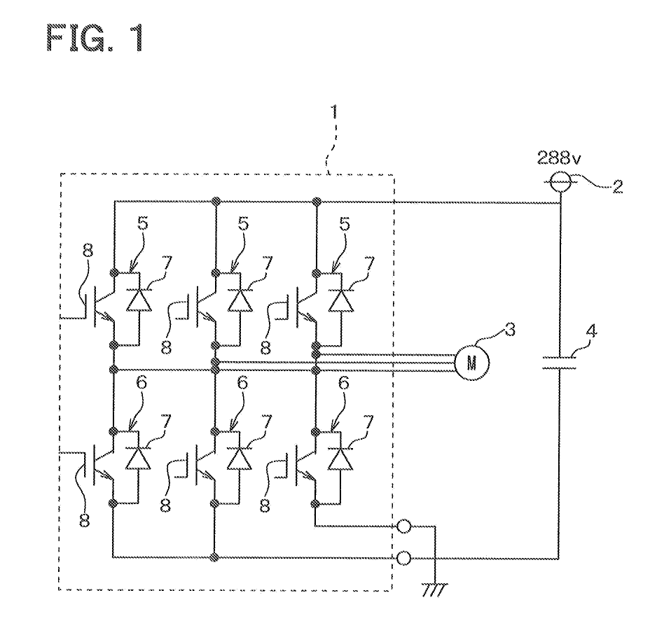

FIG. 1 is a circuit diagram of an inverter 1. As shown in FIG. 1, the inverter 1 is used to alternating-current drive a three-phase motor 3 as a load based on a direct-current power source 2.

The inverter 1 includes three series sections, each having an upper arm 5 and a lower arm 6 connected in series, corresponding to the three phases of the motor 3, and the three series sections are connected in parallel to each other. The inverter 1 successively applies the middle potential between the upper arm 5 and the lower arm 6 of each series section to corresponding one of a U-phase, a V-phase and a W-phase of the three-phase motor 3. Each of the upper arm 5 and the lower arm 6 has a lateral FWD 7 and a lateral IGBT 8. As the IGBTs 8 of the upper and lower arms 5, 6 of each series section are turned on and off, three-phase alternate currents having different cycles are supplied to the three-phase motor 3. Thus, the three-phase motor 3 can be driven.

The inverter 1 includes a smoothing capacitor 4 connected in parallel therein. The smoothing capacitor 4 reduces ripples and an influence by noise caused when the IGBTs 8 of the upper and lower arms 5, 6 are switched so as to generate a constant source voltage.

Next, a detailed structure of the lateral FWD 7 and the lateral IGBT 8 constructing the inverter 1 will be described. In each of the upper and lower arms 5, 6, the lateral FWD 7 and the lateral IGBT 8 are integrated into one chip or formed in separate chips. Although both the structures are adaptable, a structure where the lateral FWD 7 and the lateral IGBT 8 of each arm are integrated into one chip will be hereinafter described as an example.

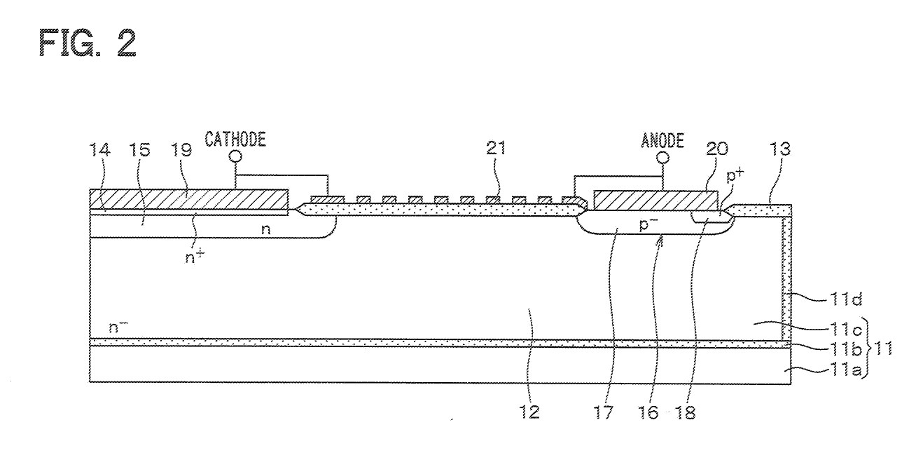

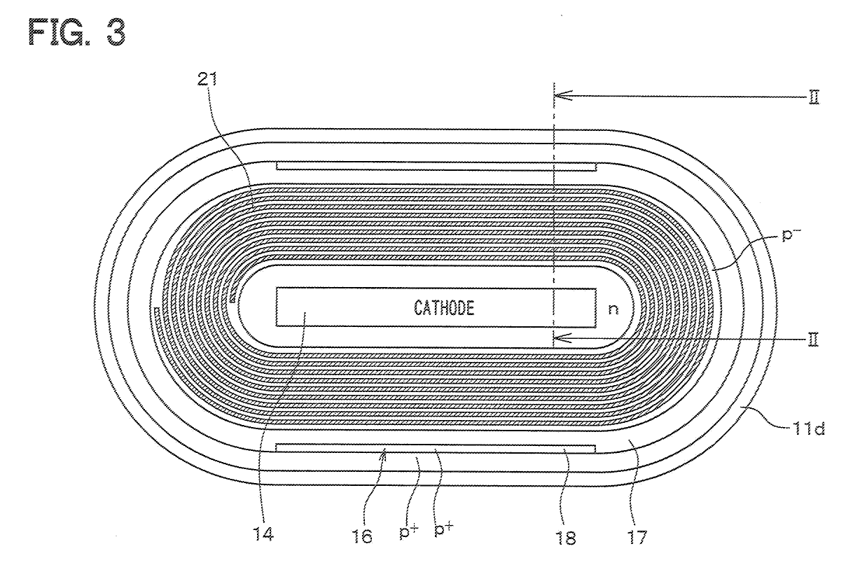

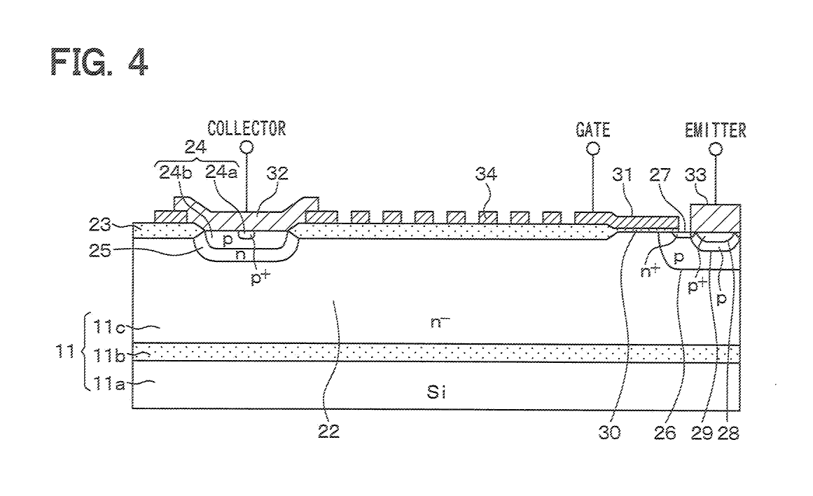

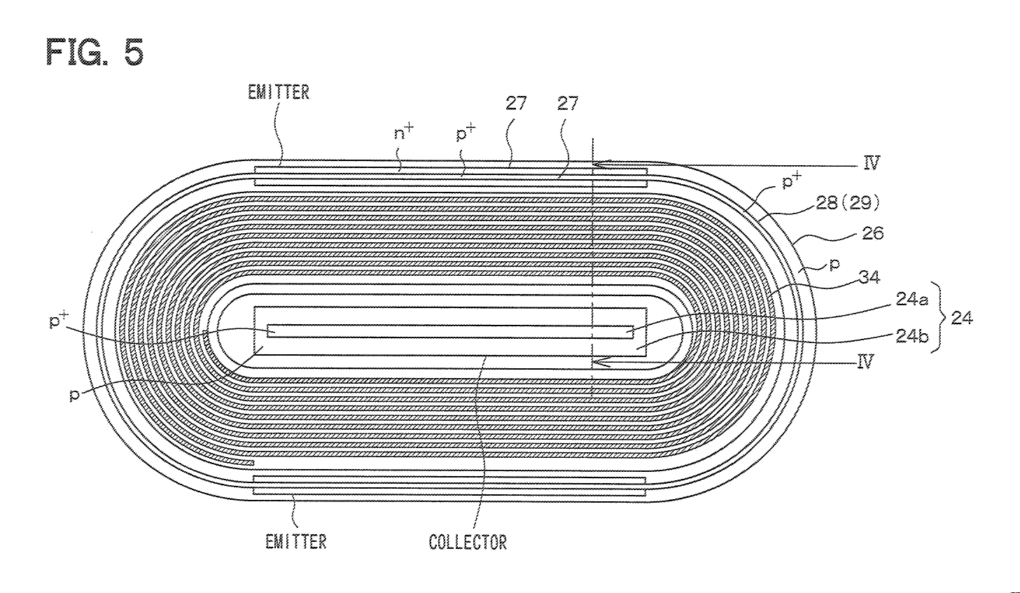

FIG. 2 is a diagram illustrating a cross-sectional structure of the lateral FWD 7 of the semiconductor device according to the present embodiment, and FIG. 3 is a diagram illustrating an upper layout of one cell of the lateral FWD 7 shown in FIG. 2. FIG. 2 corresponds to a cross-section taken along a line II-II in FIG. 3. In addition, FIG. 4 is a diagram illustrating a cross-sectional structure of the lateral IGBT 8 of the semiconductor device according to the present embodiment, and FIG. 5 is a diagram illustrating an upper layout of one cell of the lateral IGBT 8 shown in FIG. 4. FIG. 4 corresponds to a cross-section taken along a line IV-IV in FIG. 5. The detailed structure of the lateral FWD 7 and the lateral IGBT 8 will be described with reference to the above mentioned drawings.

First, the structure of the lateral FWD 7 will be described with reference to FIG. 2 and FIG. 3. In the present embodiment, as shown in FIG. 2, the lateral FWD 7 is formed using a SOI substrate 11. The SOI substrate 11 is provided by forming an active layer 11c on a support substrate 11a across an embedded oxide film (box) 11b. The support substrate 11a is made of silicon or the like. The embedded oxide film 11b corresponds to an embedded insulating film. The active layer 11c is made of silicon. In the present embodiment, the active layer 11c forms an electric conductive path of the lateral FWD 7, and components of the lateral FWD 7 are formed within the active layer 11c.

The thickness of the embedded oxide film 11b and the thickness and impurity concentration of the active layer 11c (n⁻-type drift layer 12) within the SOI substrate 11 are arbitrarily determined so as to achieve a desired withstanding voltage. For example, it is desirable that the embedded oxide film 11b has the thickness of 2 to 10 μm, preferably 5 μm or more, to withstand a high voltage. With regard to the active layer 11c, the n-type impurity concentration is, for example, 7.0×10¹⁴ cm⁻³ and the thickness is 3 to 20 μm.

In the SOI substrate 11 formed as above, a trench isolation structure 11d that surrounds each element to electrically insulate and separate the element from other elements is formed. Thus, the lateral FWD 7 is isolated from other elements through the trench isolation structure 11d. The trench isolation structure 11d is a conventionally known element isolation structure, and is provided by embedding a trench, which extends from the surface of the active layer 11c to the embedded oxide film 11b through the active layer 11c, with an insulating film or Poly-Si, for example.

A LOCOS oxide film 13, which for example has a thickness of 0.42 μm, is formed on the surface of the n⁻-type drift layer 12, as an insulating film. The components of the lateral FWD 7 are separated from each other by the LOCOS oxide film 13. Further, an n⁺-type cathode contact region 14 is formed in the surface layer portion of the n⁻-type drift layer 12 at a location where the LOCOS oxide film 13 is not formed. The n⁺-type cathode contact region 14 defines a longitudinal direction in one direction.

The periphery of the n⁺-type cathode contact region 14 is surrounded by an n-type buffer layer 15, which has an impurity concentration higher than that of the n⁻-type drift layer 12. For example, the n⁺-type cathode contact region 14 has the impurity concentration of 1.0×10²⁰ cm⁻³ and the depth of 0.2 μm. For example, the n-type buffer layer 15 has the n-type impurity concentration of 3.0×10¹⁶ cm⁻³and the depth of 5 μm.

In the surface layer portion of the n⁻-type drift layer 12, a p-type anode region 16 is formed at a portion where the LOCOS oxide film 13 is not formed while centering on the n⁺-type cathode contact region 14. The p-type anode region 16 includes a p⁻-type low impurity concentration region 17 and a p⁺-type high impurity concentration region 18.

The p⁻-type low impurity concentration region 17 is extended closer to the n⁺-type cathode contact region 14 than the p⁺-type high impurity concentration region 18, and is deeper than the p⁺-type high impurity concentration region 18. In the present embodiment, the upper layout of the p⁻-type low impurity concentration region 17 has an elliptical shape including two straight portions corresponding to the n⁺-type cathode contact region 14 and arcuate portions connecting the ends of the straight portions, as shown in FIG. 3. For example, the p⁻-type low impurity concentration region 17 has the p-type impurity concentration of 3.0×10¹⁶ cm⁻³ and the thickness of 3.1 μm.

The p⁺-type high impurity concentration region 18 is formed in the surface layer portion of the p⁻-type low impurity concentration region 17 and is in contact with the p⁻-type low impurity concentration region 17. In the present embodiment, the p⁺-type high impurity concentration region 18 is formed so that the periphery of the p⁺-type high impurity concentration region 18 is surrounded by the p⁻-type low impurity concentration region 17. The upper layout of the p⁺-type high impurity concentration region 18 has a straight shape, as shown in FIG. 3. One p⁺-type high impurity concentration region 18 is formed on each side of the n⁺-type cathode contact region 14, and thus, two p⁺-type high impurity concentration regions 18 are formed in total.

In the present embodiment, the p⁺-type high impurity concentration region 18 is formed at a location furthest from the n⁺-type cathode contact region 14 within the surface layer portion of the p⁻-type low impurity concentration region 17. For example, the p⁺-type high impurity concentration region 18 has the impurity concentration of 1.0×10²⁰ cm⁻³.

A cathode electrode 19 is formed on the surface of the n⁺-type cathode contact region 14 and is electrically connected to the n⁺-type cathode contact region 14. An anode electrode 20 is formed on the surface of the p-type anode region 16 and is electrically connected to the p-type anode region 16. The cathode electrode 19 has ohmic contact with the n⁺-type cathode contact region 14. The cathode electrode 19 has a straight shape corresponding to the n⁺-type cathode contact region 14 and is formed substantially entirely over the surface of the n⁺-type cathode contact region 14.

The anode electrode 20 has a straight shape. The anode electrode 20 is formed on opposite sides of the cathode electrode 19. The anode electrode 20 has Schottky contact or ohmic contact with the straight portion of the p⁻-type low impurity concentration region 17 of the p-type anode region 16, and has ohmic contact with the p⁺-type high impurity concentration region 18. The anode electrode 20 needs to be connected to both of the p⁻-type low impurity concentration region 17 and the p⁺-type high impurity concentration region 18 at least. In the present embodiment, the anode electrode 20 is connected to substantially the entire region of the straight portion of the p-type anode region 16.

A SRFP 21, which is a resistive layer formed by extending doped Poly-Si, is disposed on the surface of the LOCOS oxide film 13 between the cathode and the anode so that unevenness of potential gradient between the cathode and the anode is reduced. Specifically, as shown in FIG. 3, the SRFP 21 has a spiral shape wound around the cathode electrode 19 as a center. An end of the SRFP 21 is electrically connected to the cathode electrode 19 and the other end of the SRFP 21 is connected to the anode electrode 20. Therefore, in the SRFP 21, the portion connected to the cathode electrode 19 has a cathode potential, and the potential of the SRFP 21 gradually decreases toward the anode electrode 20 due to internal resistance.

Therefore, the potential of the SRFP 21 has a gradient according to the distance from the cathode electrode 19, and thus the gradient of the n⁻-type drift layer 12 located under the SRFP 21 across the LOCOS oxide film 13 can be maintained in a constant gradient. As such, electric field concentration resulting from unevenness of the potential gradient can be reduced. With this, the withstanding voltage improves as well as impact ionization is reduced, so an increase in a switching time during switching (turning off) can be restricted. Further, in the present embodiment, it is configured that the switching loss and the damage to the element can be reduced by setting the resistance value of the SRFP 21. The setting of the resistance value will be described later in detail.

The lateral FWD 7 of the present embodiment is constructed by the above described structure. In the lateral FWD 7 constructed as described above, the anode electrode 20 has the Schottky contact or the ohmic contact with the p⁻-type low impurity concentration region 17 as well as has the ohmic contact with the p⁺-type high impurity concentration region 18.

In this way, the anode electrode 20 is electrically connected to the p⁻-type low impurity concentration region 17. Because electrons are discharged to the anode electrode 20 from the surface of the p⁻-type low impurity concentration region 17, the amount of injected holes can be reduced even if the same amount of electric current is applied. Thus, the reverse recovery charge Qrr is reduced, and thus the reverse recovery capability can be improved. Further, since the amount of injected holes is reduced, the lateral FWD 7 can be operated at high speed without requiring lifetime control.

Next, the structure of the lateral IGBT 8 will be described with reference to FIG. 4 and FIG. 5. In the present embodiment, as shown in FIG. 4, the n-channel lateral IGBT 8 is formed in the same 501 substrate 11 on which the lateral FWD 7 is formed. Although not illustrated in FIG. 4, the periphery of the lateral IGBT 8 is surrounded by the trench isolation structure 11d and the lateral IGBT 8 is electrically insulated from other elements.

In the present embodiment, the active layer 11c serves as an n⁻-type drift layer 22, and components of the lateral IGBT 8 are formed on the surface layer portion of the n⁻-type drift layer 22. As described above, the thickness of the embedded oxide film 11b and the thickness and the impurity concentration of the active layer 11c in the SOI substrate 11 are arbitrarily determined so that the lateral IGBT 8 has a desired withstanding voltage.

For example, the embedded oxide film 11b has the thickness of 2 to 10 μm so as to withstand a high voltage. Further, it is preferable that the embedded oxide film 11b has the thickness of 5 μm or more so as to stably withstand 600 V or more. With regard to the active layer 11c, it is preferable that the n-type impurity concentration is 1×10¹⁴ to 1.2×10¹⁶ cm⁻³ when the thickness is 15 μm or less, and is 1×10¹⁴ to 8×10¹⁴ cm⁻³ when the thickness is 20 μm, in order to stably withstand 600 V or more.

Also on the surface of the n⁻-type drift layer 22, a LOCOS oxide film 23, which for example has the thickness of 0.42 μm, is formed. The components of the lateral IGBT are isolated from each other through the LOCOS oxide film 23. Further, a collector region 24, which defines a longitudinal direction in one direction, is formed in the surface layer portion of the n⁻-type drift layer 22 at a location where the LOCOS oxide film 23 is not formed, as shown in FIG. 5. The collector region 24 includes portions having different impurity concentrations, such as a p⁺-type portion 24a as a high impurity concentration region having a relatively high impurity concentration and a p-type portion 24b as a low impurity concentration region having an impurity concentration lower than that of the high impurity concentration region.

The p⁺-type region 24a has a surface concentration of 1×10¹⁹ to 1×10²⁰ cm⁻³, for example. The p-type region 24b has a surface concentration of 1×10¹⁶ to 1×10¹⁹ cm⁻³ or 1×10¹⁵ to 1×10¹⁸ cm⁻³, for example. In the present embodiment, as shown in FIG. 4 and FIG. 5, the p⁺-type region 24a and the p-type region 24b both have a rectangular shape defining a longitudinal direction in one direction, and the periphery of the p⁺-type region 24a is surrounded by the p-type region 24b.

The periphery of the collector region 24 is surrounded by an n-type buffer layer 25 having an impurity concentration higher than that of the n⁻-type drift layer 22. The n-type buffer layer 25 serves as a FS (Field Stop) layer. The n-type buffer layer 25 is constructed of an n-type layer having the impurity concentration higher than that of the n-type drift layer 22. The n-type buffer layer 25 restricts expansion of a depletion layer so as to improve the withstanding voltage and steady loss in performance. For example, the n-type impurity concentration of the n-type buffer layer 25 is 4×10¹⁶ to 1×10¹⁸ cm⁻³.

A channel p well layer 26, an n⁺-type emitter region 27, a p⁺-type contact layer 28 and a p-type body layer 29 are formed around the collector region 24 as a center in the surface layer portion of the n⁻-type drift layer 22 at locations where the LOCOS oxide film 23 is not formed.

The channel p well layer 26 serves to form a channel region on a surface. For example, the channel p well layer 26 has the thickness of 2 μm or less, and the width of 6 μm or less. The channel p well layer 26 is formed concentric with the collector region 24 and entirely surrounds the periphery of the collector region 24.

The n⁺-type emitter region 27 is formed in the surface layer portion of the channel p well layer 26 and ends inside of an end position of the channel p well layer 26. Also, the n⁺-type emitter region 27 is formed to extend in the longitudinal direction of the collector 24. As shown in FIG. 5, the n⁺-type emitter region 27 is not formed at corner portions of the collector region 24, that is, at both the ends of the collector region 24 with respect to the longitudinal direction. The n⁺-type emitter region 27 has a straight shape that is parallel to the collector region 24. In the present embodiment, the n⁺-type emitter region 27 is disposed on each of the opposite sides of the p⁺-type contact layer 28 and p-type body layer 29.

The p⁺-type contact layer 28 serves to fix the channel p well layer 26 to an emitter potential, and has an impurity concentration higher than that of the channel p well layer 26. As shown in FIG. 5, the p⁺-type contact layer 28 is disposed concentric with the collector region 24 as a center, and entirely surrounds the periphery of the collector region 24.

The p-type body layer 29 serves to reduce voltage drop resulting from a hole current flowing from the collector to the emitter through the surface. The p-type body layer 29 is formed concentric with the collector region 24 as the center and entirely surrounds the periphery of the collector region 24. The p-type body layer 29 restricts a parasitic npn transistor constructed of the n⁺-type emitter region 27, the channel p well layer 26 and the n⁻-type drift layer 22 from being operated, and thus the turning off time can be improved.

Further, as show in FIG. 5, the channel p well layer 26, the n⁺-type emitter region 27, the p⁺-type contact layer 28 and the p-type body layer 29 are formed on each of opposite sides of the collector region 24 in each cell.

In addition, a gate electrode 31 is formed on the surface of the channel p well layer 26 across a gate insulation film 31. The gate electrode 31 is made of doped Poly-Si or the like. As a gate voltage is applied to the gate electrode 31, a channel region is formed at a surface portion of the channel p well layer 26.

Also, a collector electrode 32 is formed on the surface of the collector region 24 and is electrically connected to the collector region 24, and an emitter electrode 33 is formed on the surface of the n⁺-type emitter region 27 and the p⁺-type contact layer 28 and is electrically connected to the n⁺-type emitter region 27 and the p⁺- type contact layer 28.

The collector electrode 32 has ohmic contact with the p⁺-type region 24a, and has Schottky contact with the p-type region 24b.

A SRFP 34 is formed on the surface of the LOCOS oxide film 23 between the collector and the gate. The SRFP 34 is provided by a resistive layer formed by extending doped Poly-Si so that unevenness of potential gradient between the collector and the gate is reduced. Specifically, as shown in FIG. 5, the SRFP 34 has a spiral shape wound around the collector electrode 32 as the center. An end of the SRFP 34 is electrically connected to the collector electrode 32 and the other end of the SRFP 34 is connected to the gate electrode 31.

Therefore, the SRFP 34 has a collector potential at the position connected to the collector electrode 32, and the potential gradually decreases toward the emitter as a function of distance from the collector electrode 32 due to internal resistance. As such, the potential of the SRFP 34 has gradient according to the distance from the collector electrode 32, and the potential of the n⁻-type drift layer 22 located under the SRFP 34 across the LOCOS oxide film 32 can be maintained in a constant gradient. As such, electric field concentration resulting from unevenness of the potential gradient can be reduced. With this, the withstanding voltage is improved as well as impact ionization is reduced, so an increase in a switching time during switching (turning off) can be restricted.

Further, similar to the SRFP 21 of the lateral FWD 7, the resistance value of the SRFP 34 is set so that the switching loss and the damage to the element can be reduced. Here, the end of the SRFP 34 is connected to the gate electrode 31. Alternatively, the end of the SRFP 34 can be connected to the emitter electrode 33.

The lateral IGBT 8 according to the present embodiment is constructed by the above described structure. In the IGBT 8 having the above described structure, as a desired gate voltage is applied to the gate electrode 31, a channel region is formed on the surface layer portion of the channel p well layer 26, which is located under the gate electrode 31 between the n⁺-type emitter region 27 and the n⁻-type drift layer 22 so that electrons flow into the n⁻-type drift layer 22 from the emitter electrode 33 and the n⁺-type emitter region 27 through the channel region. With this, holes flow into the n⁻-type drift layer 22 through the collector electrode 32 and the collector region 24 so that conductivity modulation occurs within the n⁻-type drift layer 22. As such, an IGBT operation to generate a large electric current between the emitter and the collector is conducted.

In such a lateral IGBT 8, in the present embodiment, the collector electrode 32 has the ohmic contact with the p⁺-type region 24a and the Schottky contact with the p-type region 24b. Therefore, injection efficiency is reduced by restricting the hole injection from the collector side. Specifically, since the hole injection is restricted by such a contact shape between the collector electrode 32 and the collector region 24, the n-type buffer layer 25 does not need to have a function of restricting the hole injection. The n-type buffer layer 25 needs to simply serve as the FS layer. Therefore, it is possible to set the impurity concentration of the buffer layer 25 to a level without changing the injection efficiency on the collector side.

The lateral FWD 7 and the lateral IGBT 8 of each of the upper and lower arms 5, 6 are constructed by the above described structure. In the present embodiment, further, the resistance value of each of the SRFP 21 of the lateral FWD 7 and the SRFP 34 of the lateral IGBT 8 is adjusted so that the switching loss and the damage to the element can be restricted. Hereinafter, the concept of setting the resistance value of the SRFPs 21, 34 will be described. The basic concept is the same between the lateral FWD 7 and the lateral IGBT 8. Therefore, the setting of the resistance value of the SRFP 21 will be exemplarily described.

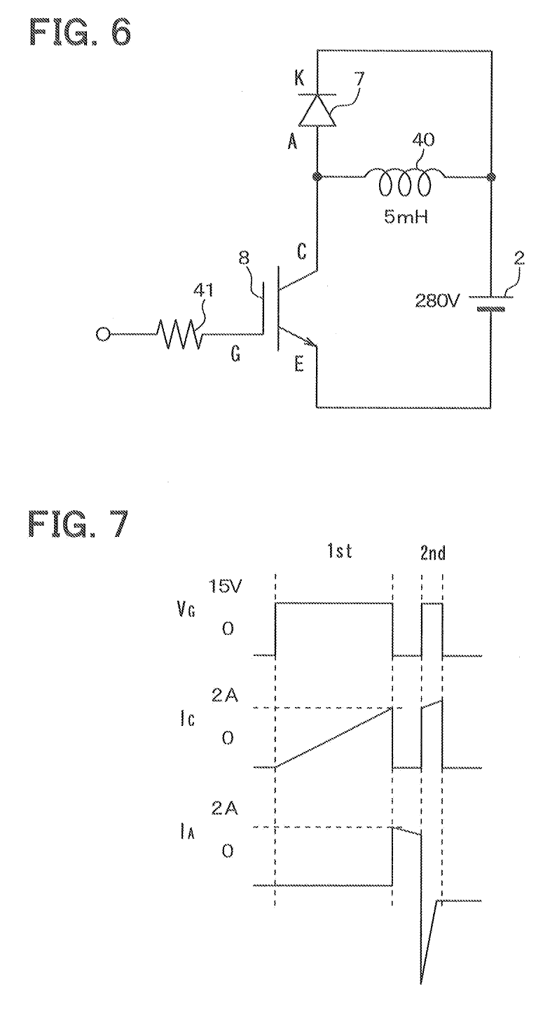

FIG. 6 is a circuit diagram illustrating a recovery characteristic evaluation circuit using the lateral FWD 7 and the lateral IGBT 8. The recovery characteristic evaluation circuit is provided by obtaining main components of one phase of the inverter 1 at the time of turning off. In the recovery characteristic evaluation circuit, it is assumed that electric power is supplied from the direct current power source 2 to a L load 40 corresponding to the three-phase motor 3, and recovery characteristic is evaluated by controlling the gate voltage to the gate electrode 31 of the lateral IGBT 8 through a resistor 41.

FIG. 7 is a time chart of respective components when the recovery characteristic evaluation circuit is used. As shown in FIG. 7, a double-pulse is applied so that the lateral IGBT 8 is turned on once by applying a predetermined voltage (for example, 15V) as the gave voltage V_{G} to the gate electrode 31, is then instantaneously turned off when a collector current I_{c} reaches a predetermined rated current (for example, 2 A), and is turned on again. The recovery loss at the time of turning off is detected by applying the double-pulse. Specifically, the waveform of the anode current I_{A} when the lateral IGBT 8 is turned on again is observed. As a result, it is appreciated that, after the first peak where the anode current I_{A} (recovery current) is largely reduced at the time of turning on, the amount of decrease in the anode current I_{A} increases and the second peak appears.

The first peak of the above two peaks inevitably occurs at the beginning of the recovery. In order to investigate the cause of occurrence of the second peak, a device simulation is performed.

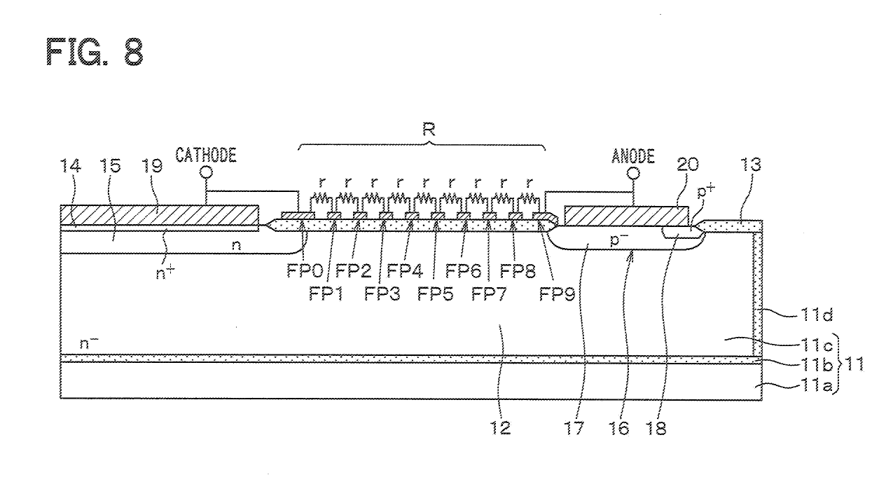

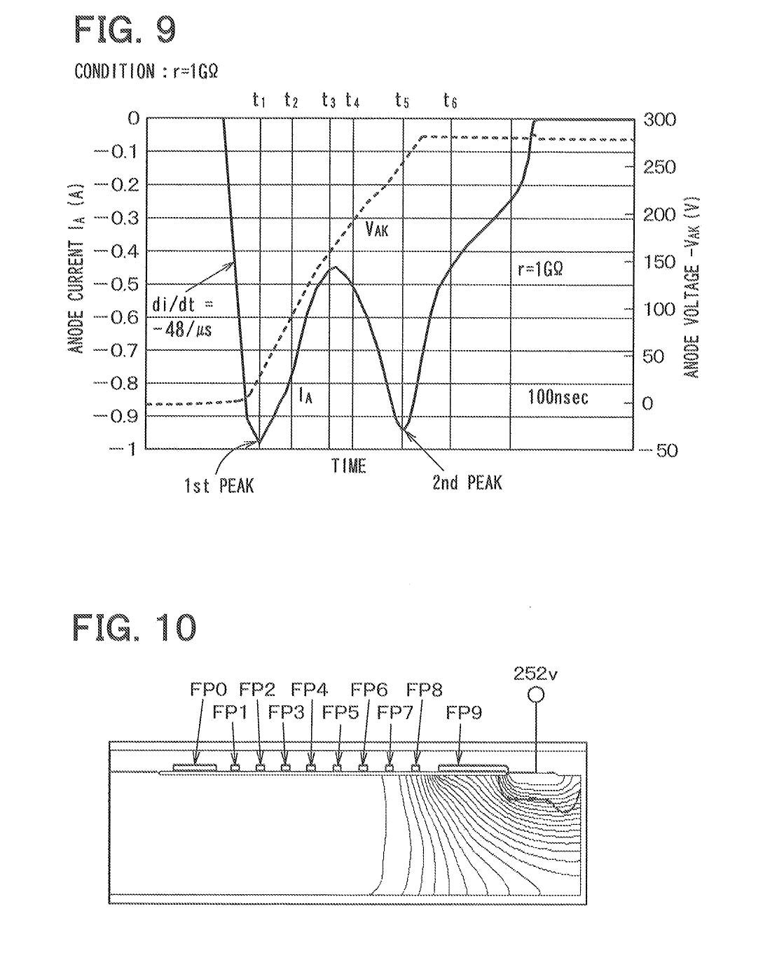

However, it is difficult to perform simulation using the SRFP 21 having the spiral pattern. Therefore, the evaluation is conducted in the simulation using the lateral FWD 7 having a cross-section as shown in FIG. 8. That is, as shown in FIG. 8, it is assumed that ten separate ring-shaped field plates FP0-FP9 are arranged at intervals on the LOCOS oxide film 13, and the evaluation is conducted using the structure where the field plates FP0-FP9 are connected while considering the resistance r of one lap of each field plate. As a result, the result shown in FIG. 9 is obtained.

FIG. 9 is a diagram, illustrating waveforms of the anode voltage V_{AK} and the anode current I_{A} at the time of recovery. With regard to the anode voltage V_{AK}, because the cathode is connected to a positive terminal of the power source 2, it is represented as −VAK so that the polarity is inversed. Further, considering the loss of the SRFP 21, it is ideal to set the resistance value of the SRFP 21 to infinity. Therefore, the resistance value of the resistance r provided by the SRFP 21 is set to 1 GΩ. Furthermore, to make the occurrence of the second peak noticeable, as an operation condition, an initial rate of decrease di/dt of the anode current I_{A} at the time of recovery is set to 48 A/μs, which is approximately four times of an experimental value.

As shown in FIG. 9, the anode current I_{A} (recovery current) is largely decreased at the moment of turning on and the first peak appears at the timing t1. The amount of decrease in the anode current I_{A} is reduced from the timing t1 to the timing t3. Thereafter, the amount of decrease in the anode current I_{A} is increased again and the second peak having the similar value as the first peak appears at the timing t5. It is obvious that dynamic avalanche occurs at the second peak. The recovery loss corresponds to a time integration value of the product of the anode current I_{A} and the anode voltage V_{AK}, and is proportional to an area surrounded by the waveform of the anode current I_{A} and the X-axis since the anode voltage V_{AK} is substantially constant in FIG. 9. Therefore, the recovery loss has a larger value with an increase in the amount of decrease in the anode current I_{A} at the first peak and the second peak. Therefore, the recovery loss can be reduced by reducing the second peak.

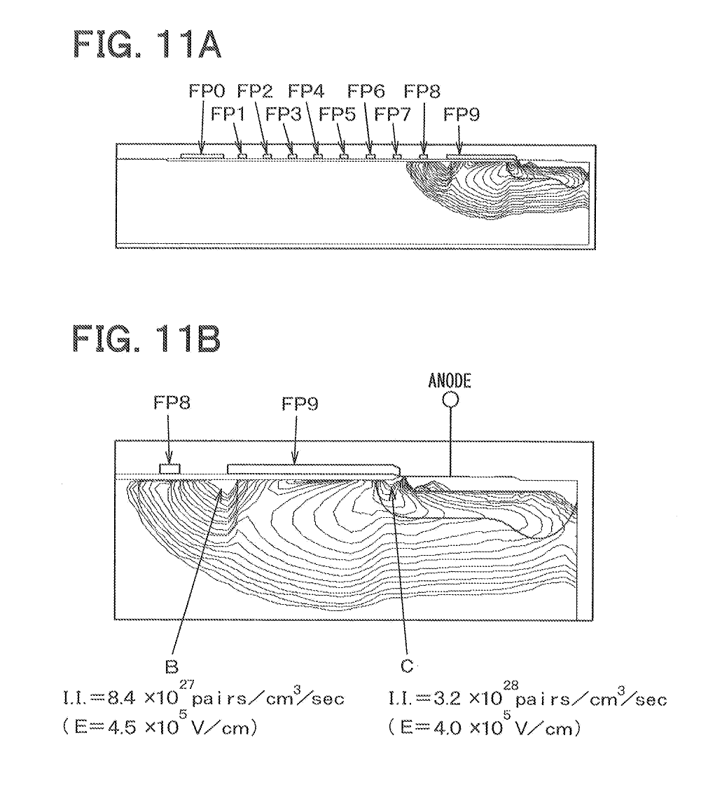

Next, a state of electrons within the lateral FWD 7 is analyzed. FIG. 10 is a diagram illustrating equipotential distribution above the n⁻-type drift layer 12 at the second peak (the timing t5 in FIG. 9), in the cross-sectional view shown in FIG. 8. FIG. 11A is a diagram illustrating an impact ionization rate above the n⁻-type drift layer 12 at the second peak, in the cross-sectional view shown in FIG. 8, and FIG. 11B is a diagram illustrating an enlarged view around the anode in FIG. 11A.

As shown in FIG. 10, it is appreciated that the depletion layer is limited around the anode, and that electric field intensity due to the field concentration is high around the anode. In addition, as considering the impact ionization rate from FIG. 11A and FIG. 11B, it is appreciated that the impact ionization rate is high at a point B and a point C in FIG. 11B. At the point C, that is, at an end of the field plate FP9 opposite to the field plate FP8, the impact ionization rate is high because carriers are drawn through the point C at the time of recovery, and the increase in the impact ionization rate at the point C usually occurs. On the other hand, it is considered that the increase in the impact ionization rate at the point B, that is, at an end of the field plate FP9 adjacent to the field plate 8 is caused by an increase in electric field intensity at the silicon surface between the field plate FP8 and the field plate FP9.

Next, the cause of the increase in the electric field intensity at the silicon surface between the field plate FP8 and the field plate FP9 at the timing t5 where the second peak occurs is analyzed in a state where the resistance value of the resistance r provided by the SRFP 21 is set to 1 GΩ. Specifically, the time change in potential of each of ten field plates FP0-FP9 is analyzed. FIG. 12 shows the result of the analysis.

As shown in FIG. 12, the anode potential V_{AK} is 250 V at the timing t5, and is substantially recovered to the power source voltage. However, as checking the potential of each of the field plates FP0-FP9, the potential V_{FP8} of the field plate FP8 is 60V, and thus a potential difference (V_{FP9}-V_{FP8}) between the field plate FP8 and the field plate FP9 is 190V. Therefore, it is appreciated that approximately ¾ of 250V of the anode potential V_{AK} is distributed to a portion between the field plate FP8 and the field plate FP9, and the potential distribution is very uneven in the SRFP 21. It can be said that the high electric field between the field plate FP8 and the field plate FP9 results from such unevenness of the potential distribution.

It is considered that such unevenness of the potential distribution is caused because the resistance value of the resistance r provided by the field plates FP0-FP9 is high. As described above, the resistance value of the SRFP 21 should be as high as possible, ideally infinity, considering the loss in the SRFP 21. According to the above described analysis, however, it is appreciated that an excessively large resistance value of the SRFP 21 is not preferable, considering the switching characteristic, that is, the recovery loss.

Therefore, the recovery waveform when the resistance value of the resistance r provided by the field plates FP0-FP9 is reduced is analyzed in order to alleviate the unevenness of the potential distribution. FIG. 13 shows the result of the analysis. As shown in FIG. 13, it is appreciated that the amount of decrease of the anode current I_{A} at the second peak is minimum when the resistance value of the resistance r is lowered to 100 kΩ.

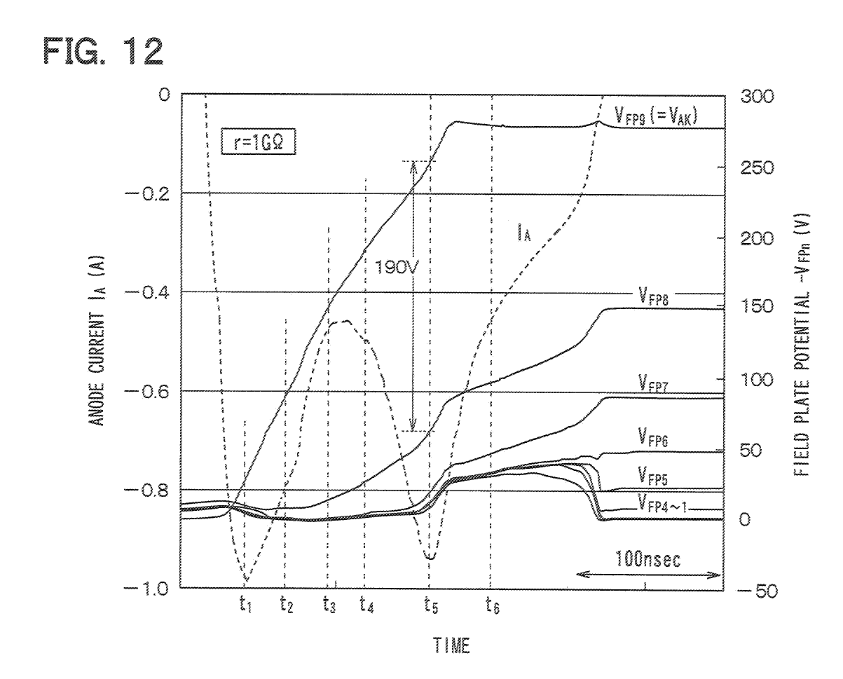

Therefore, the time change in the potential of each of ten field plates FP0-FP9 when the resistance value of the resistance r is 100 kΩ is analyzed. FIG. 14 shows the result of the analysis. As shown in FIG. 14, at the timing t5, the anode potential V_{AK} is 270V and is almost recovered to the power source voltage. As checking the potential of each of the field plates FP0-FP9, the potential V_{FP8} of the field plate FP8 is 180V, and thus the potential difference (V_{FP9}−V_{FP8}) between the field plate FR8 and the field plate FP9 is 90V. Therefore, it is appreciated that approximately ⅓ of 270V of the anode voltage V_{AK} is distributed to a portion between the field plate FP8 and the field plate FP9, and the potential is distributed relatively evenly in the SRFP21.

As such, it can be said that the smaller resistance value of the SRFP 21 is preferable, considering the switching characteristic, that is, the recovery loss at the time of turning on. That is, the potential distribution is even between the field plates FP0-FP9 with the decrease in the resistance value of the SRFP 21, resulting in the decrease in the electric field intensity between the field plate FP8 and the field plate FP9. Therefore, the impact ionization rate is decreased, and hence the second peak can be restricted.

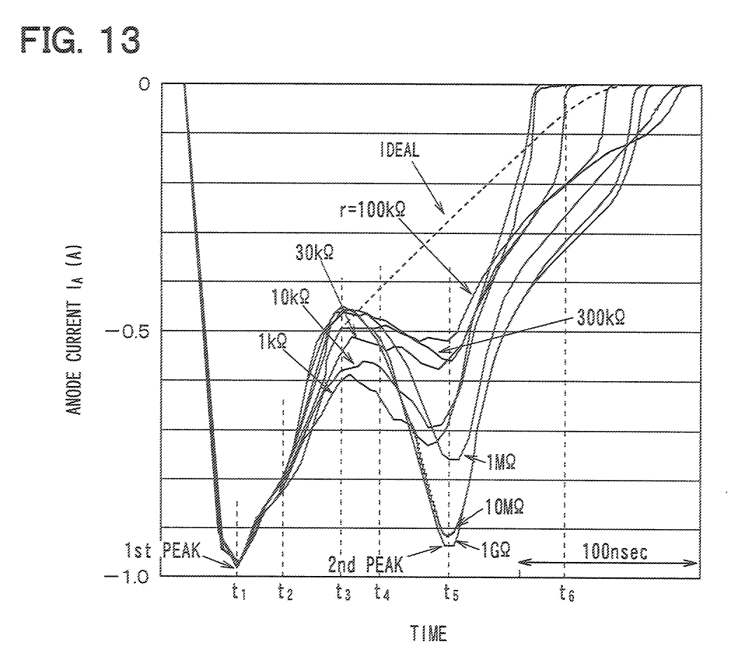

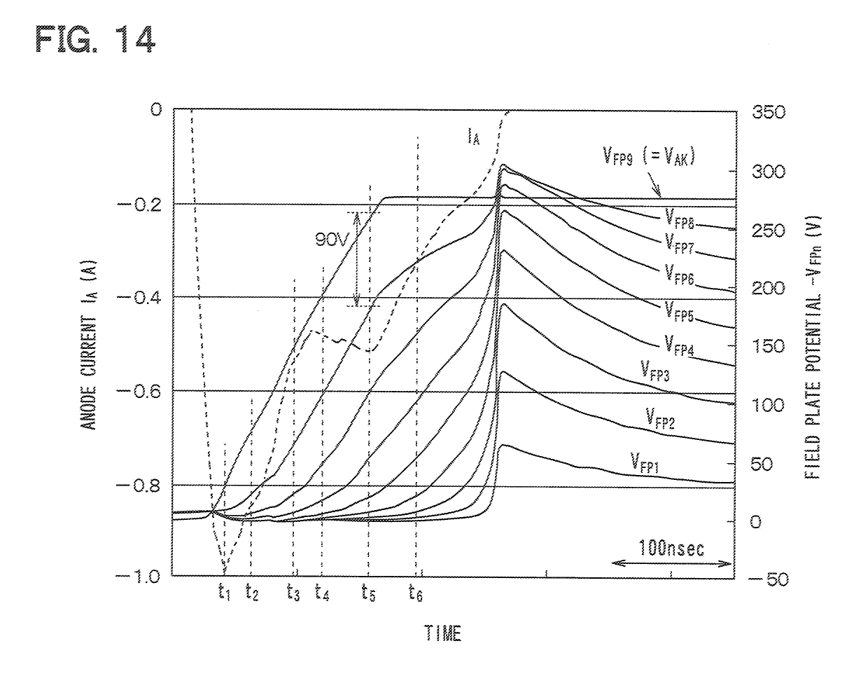

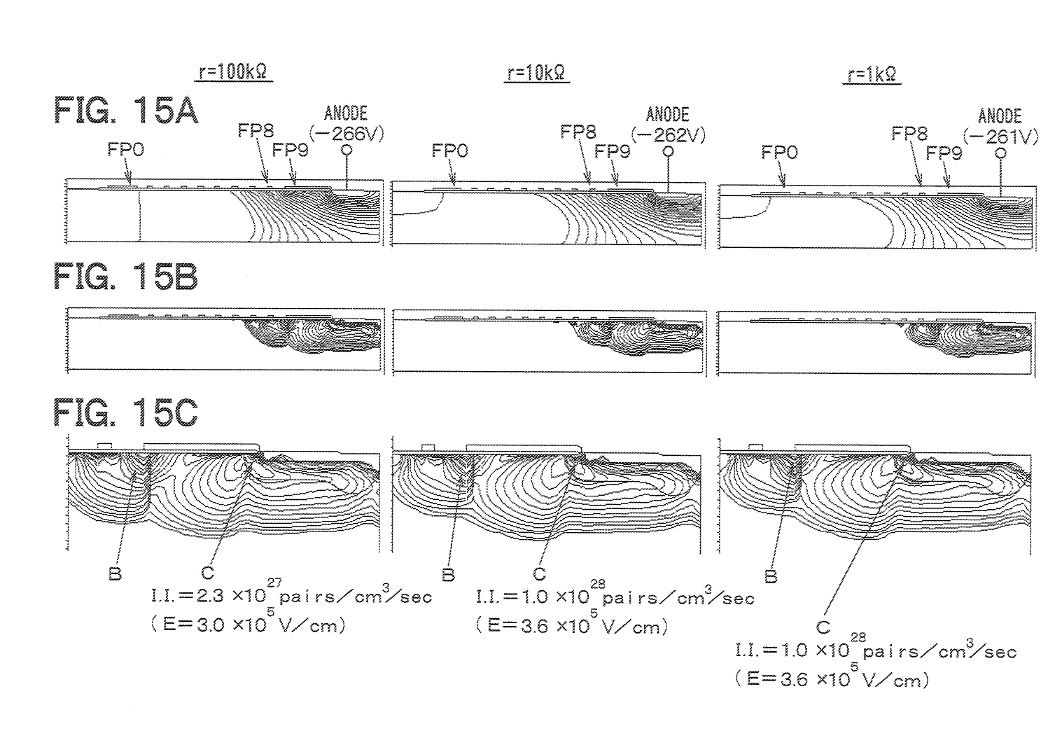

It is to be noted that, when the resistance value of the resistance r is further reduced from 100 kΩ, the anode current I_{A} contrary increases at the second peak again. To investigate the cause of the above phenomenon, the equipotential distribution and the impact ionization rate distribution are examined by varying the resistance value of the resistance r at the timing t5. FIGS. 15A and FIG. 15B show the examination result. FIG. 15A is a diagram illustrating the equipotential distribution, FIG. 15B is a diagram illustrating the impact ionization rate, and FIG. 15C is a diagram illustrating an enlarged view around the anode of FIG. 15B.

As shown in FIG. 15A through 15C, as the equipotential distribution and the impact ionization rate distribution are examined by setting the resistance value of the resistance r to 100 kΩ, 10 kΩ and 1 kΩ respectively, the potential distribution between the adjacent field plates FP0-FP9 becomes even with a decrease in the resistance value. Therefore, the electric field intensity between the field plate FP8 and the field plate FP9 reduces, and the impact ionization rate at the point B reduces. On the other hand, at the point C corresponding to the end of the field plate FP9 opposite to the field plate FP8, the impact ionization rate increases. This increase in the impact ionization rate causes the anode current I_{A} to increase again at the second peak.

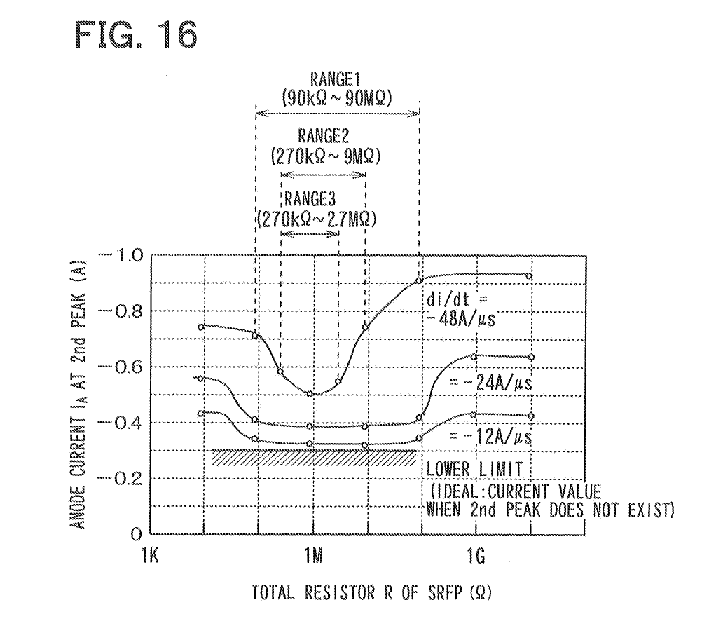

The resistance r that can restrict the increase in the anode current I_{A} at the second peak can be found based on the above simulation analyses. In the above simulations, it is assumed that the ring-shaped separate field plates FP0-FP9 are arranged at intervals. Thus, the resistance value of the total resistance R of the SRFP 21 is provided by connecting between all the field plates FP0-FP9. Further, since it is assumed that nine resistors r exist between the adjacent field plates FP0-FP9, the total resistance R is provided by the total resistance value of the nine resistors (9×r). The amount of decrease in the anode current I_{A} at the second peak with respect to the total resistance R of the SRFP 21 is examined by varying the rate of decrease di/dt of the initial anode current I_{A} at the time of recovery in the state where the thickness of the LOCOS oxide film 13 is 0.42 μm. FIG. 16 shows the examination result.

As shown in FIG. 16, it is appreciated that the amount of decrease in the anode current I_{A} at the second peak can be reduced in a range where the resistance value of the total resistance R of the SRFP 21 is 90 kΩ and 90 MΩ, in any of the cases where the rate of decrease di/dt of the initial anode current Iᵥ at the time of recovery is −12, −24 and −48 A/μs, as compared with a range lower than 90 kΩ and higher than 90 MΩ.

Particularly, in the range where the resistance value of the total resistance R of the SRFP 21 is from 270 kΩ to 2.7 MΩ, the amount of decrease in the anode current I_{A} at the second peak can be reduced even in the case where the rate of decrease di/dt is −48 μs. At least, when the total resistance R of the SRFP 21 is in a range between 270 kΩ and 9 MΩ, approximately ½ of the decrease of the anode current I_{A} of the second peak is achieved, as compared with the case of 900 kΩ where the amount of decrease in the anode current I_{A} from the region where the resistance value of the total resistance R is lower than 90 kΩ and the region where the resistance value of the total resistance R is higher than 90 MΩ is maximum.

Therefore, the increase in the decrease amount of the anode current I_{A} at the second peak can be restricted when the resistance value of the total resistance R of the SRFP 21 is in a range between 90 kΩ and 90 MΩ, preferably in a range between 270 kΩ and 9 MΩ, more preferably in a range between 270 kΩ and 2.7 MΩ. As such, the switching loss and the damage of the lateral FWD 7 can be reduced.

It has been described about the case where the thickness of the LOCOS oxide film 13 is 0.42 μm. The effect of the electric field with respect to the resistance value of the SRFP 21 varies depending on the thickness of the LOCOS oxide film 13, and thus the amount of decrease in the anode current I_{A} at the second peak also varies. However, even if the thickness of the LOCOS oxide film 13 is not 0.42 μm, the similar advantageous effects can be achieved at least by setting the resistance value of the total resistance R of the SRFP 21 in the range between 90 kΩ and 90 MΩ.

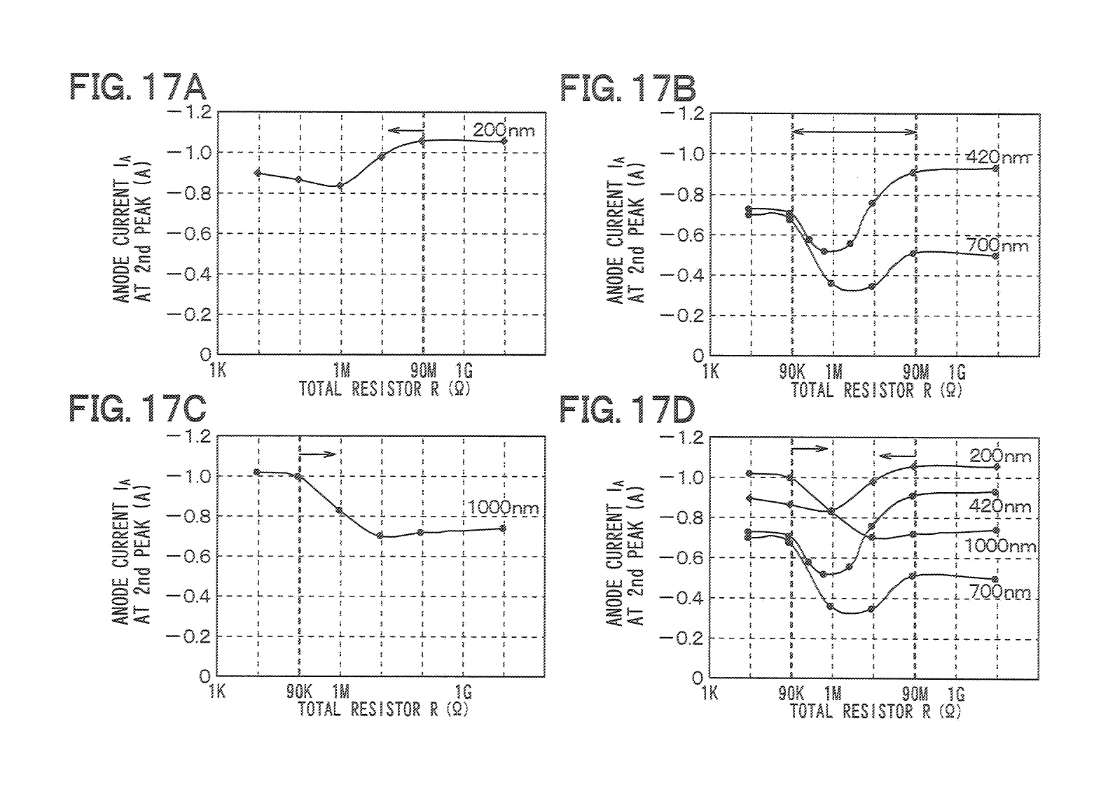

FIG. 17 A through FIG. 17C are graphs illustrating a relationship between the resistance value of the total resistance R of the SRFP 21 and the amount of decrease in the anode current I_{A} at the second peak where the thickness of the LOCOS oxide film 13 is varied, and FIG. 17D is a graph including curves of FIG. 17A through FIG. 17C.

As shown in FIG. 17A, when the thickness of the LOCOS oxide film 13 is 200 nm, the amount of decrease in the anode current I_{A} at the second peak is reduced in the condition where the resistance value of the total resistance R of the SRFP 21 is equal to or lower than 90 MΩ. As shown in FIG. 17B, when the thickness of the LOCOS oxide film 13 is 420 nm, the amount decrease in the anode current I_{A} at the second peak is reduced in a range where the resistance value of the total resistance R of the SRFP 21 is from 90 kΩ and 90 MΩ. Also in the case where the thickness of the LOCOS oxide film 13 is 700 nm, the similar result to the case where the thickness is 420 nm is achieved. Further, as shown in FIG. 17C, when the thickness of the LOCOS oxide film 13 is 1000 nm, the amount of decrease in the anode current I_{A} at the second peak is reduced in a range where the resistance value of the total resistance R of the SRFP 21 is equal to or higher than 90 kΩ.

As the above results are included in FIG. 17D, when the thickness of the LOCOS oxide film 13 is at least in a range between 200 nm and 1000 nm, the amount of decrease in the anode current I_{A} at the second peak can be reduced in a range where the resistance value of the total resistance R of the SRFP 21 is from 90 kΩ and 90 MΩ.

Although the lateral FWD 7 has been exemplarily described, the similar advantageous effects can be achieved in the lateral IGBT 8. By setting the resistance value of the SRFP 34 of the lateral IGBT 8 similar to the resistance value of the SRFP 21 of the lateral FWD 7, the switching loss and the damage of the lateral IGBT 8 can be reduced.

As described above, in a lateral element such as the lateral FWD 7 and the lateral IGBT 8, the increase in the decrease amount of the anode current I_{A} or the like at the second peak can be restricted by setting the resistance value of the total resistance R of the SRFP 21, 34 in the range between 90 kΩ and 90 MΩ, preferably in the range between 270 kΩ and 27 MΩ, more preferably in the range between 900 kΩ and 9 MΩ. Accordingly, even if the switching operation is conducted at a high speed, the avalanche breakdown is restricted, and the switching loss and the damage of the lateral FWD 7 can be reduced.

### Second Embodiment

A second embodiment of the present invention will be described hereinafter. In the present embodiment, the structure of the SRFP 21, 34 is modified from that of the first embodiment, and other structures are similar to the first embodiment. Thus, a part different from the first embodiment will be mainly described.

In the first embodiment, the resistance value of the total resistance R of the SRFP 21, 34 of the lateral element such as the lateral FWD 7 and the lateral IGBT 8 is adjusted. In such a case, it is assumed that the resistance value of the SRFP 21, 34 is constant in the longitudinal direction. Alternatively, the resistance value of the SRFP 21, 34 is not limited to be constant in the longitudinal direction, but may be varied in the longitudinal direction.

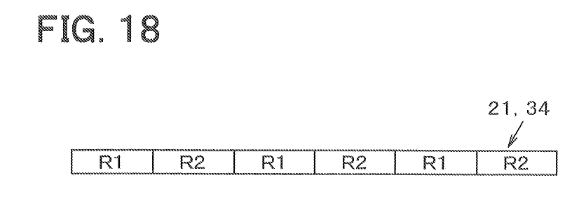

FIG. 18 is an enlarged view of a part of the SRFP 21, 34 of the lateral FWD 7 and the lateral IGBT 8 when viewed from the top, As shown in FIG. 18, the SRFP 21, 34 has portions that provides regions R1, R2 having different specific resistances with respect to the longitudinal direction. The resistance value per unit length is varied by varying the portions providing the regions R1, R2 having different specific resistances and the length with respect to the longitudinal direction as a function of distance from the cathode or the collector toward the anode or the emitter.

Such a structure is, for example, achieved by forming the SRFP 21, 34 of doped Poly-Si, and varying a doping concentration of impurity to the poly-silicon using a mask having a pattern according to the concentration distribution. For example, the doping concentration is varied by the following method. First, at a position where the impurity concentration is relatively high in the SRFP 21, 34, the impurity is doped beforehand through an opening of the mask. Then, after the mask is removed, side impurity is doped so that the impurity is doped also to a portion where the impurity concentration is relatively low and the impurity concentration of that portion is lower than that of the portion where the impurity concentration is relatively high.

In such a case, the resistance value of the SRFP 21, 34 is varied so that the resistance value per unit length is small adjacent to the cathode and the collector, and is larger adjacent to the anode and the emitter than the cathode and the collector. That is, the above described electric field concentration between the field plate FR8 and the field plate FP9 is caused, when the voltage is instantaneously changed at the time of switching, because it is difficult to follow the change in the voltage as a function of distance from a position where the voltage is changed due to the time constant.

Therefore, it is possible to follow the change in voltage at the time of switching at a position away from the changing position by reducing the resistance value per unit length adjacent to the cathode and the collector. Accordingly, it is possible to reduce switching loss and the damage of the lateral FWD 7 and the lateral IGBT 8.

### Third Embodiment

A third embodiment of the present invention will be described. The present embodiment employs a semiconductor substrate other than the 301 substrate 1 of the first embodiment, and structures of the present embodiment other than the semiconductor substrate are similar to those of the first embodiment. Therefore, a different structure will be mainly described.

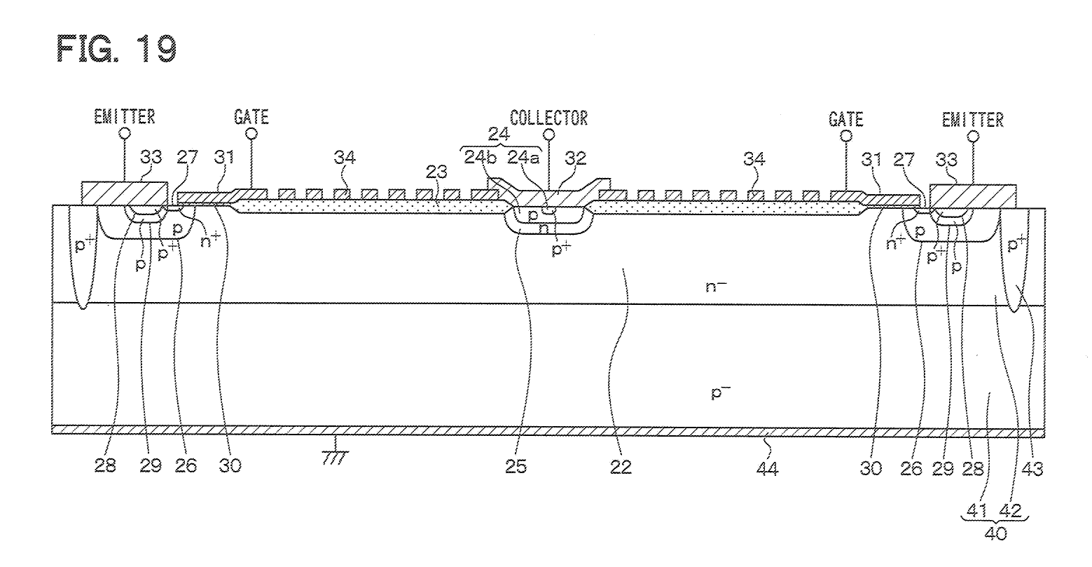

FIG. 19 is a diagram illustrating a cross-sectional structure of the n-channel lateral IGBT 8 according to the present embodiment. As shown in FIG. 19, a semiconductor substrate 40 in which an n⁻-type layer 42 is formed on a p⁻-type silicon substrate 41 is used. Further, the n⁻-type drift layer 22 is provided by the n⁻-type layer 42, and a p⁺-type isolation region 43 is formed to extend from the surface of the n⁻-type drift layer 22 to the p⁻-type silicon substrate 41.

The p⁺-type isolation region 43 is formed to surround the periphery of the lateral IGBT 8, and a junction isolation structure is provided by PN junction between the p⁺-type isolation region 43 and the n⁻-type drift layer 22. A GND pattern 44 is formed on a rear surface of the semiconductor substrate 40. The p⁻-type silicon substrate 41 is grounded because the GND pattern 44 is grounded.

In this way, the lateral IGBT 8 can be configured in the junction isolation type using a simple silicon substrate as the p⁻-type silicon substrate 41 for the semiconductor substrate 40.

Although it has been described with regard to the lateral IGBT 8 as an example, the lateral FWD 7 can be also formed using the semiconductor substrate 40 having the similar structure.

### Fourth Embodiment

A fourth embodiment of the present invention will be described. The present embodiment also employs a semiconductor substrate other than the SOI substrate 1 of the first embodiment, and structures of the present embodiment other than the semiconductor substrate are similar to those of the first embodiment. Therefore, a different structure will be mainly described.

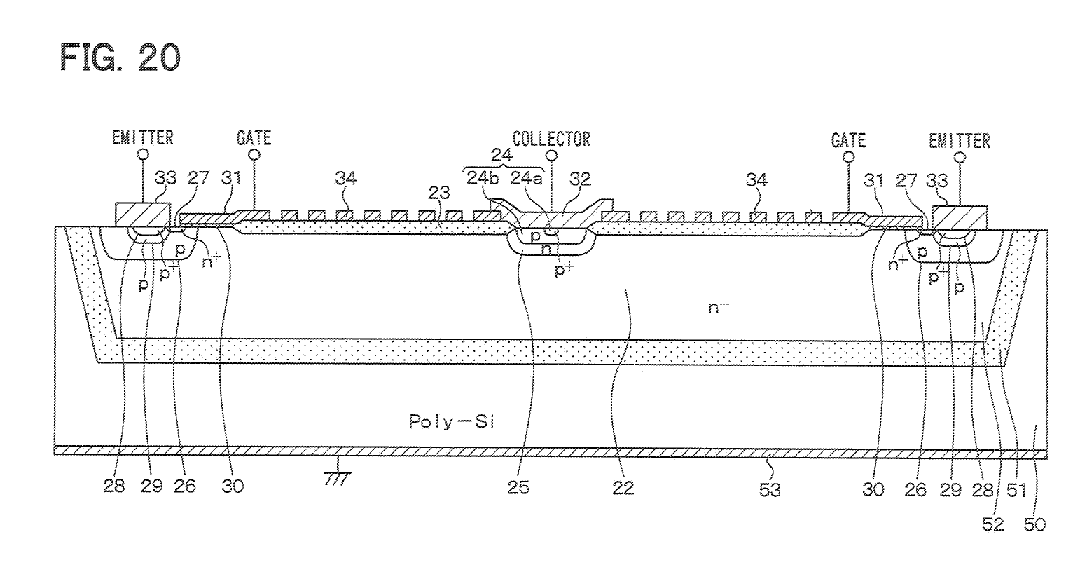

FIG. 20 is a diagram illustrating a cross-sectional structure of the n-channel lateral IGBT 8 according to the present embodiment. As shown in FIG. 20, a semiconductor substrate 50 made of poly-silicon is employed. A silicon oxide film 51 is formed to surround a formation region where the lateral IGBT 8 is formed in the semiconductor substrate 50, and an n⁻-type silicon layer 52 is provided in an area inside of the silicon oxide film 51.

The lateral IGBT 8 is configured by using the layer 52 as the n⁻-type drift layer 22. That is, the lateral IGBT 8 is dielectric isolation. A GND pattern 53 is formed on a rear surface of the semiconductor substrate 50, and the semiconductor substrate 50 is grounded because the GND pattern 53 is grounded.

In this way, the lateral IGBT 8 can be the dielectric isolation type where the n⁻-type drift layer 22 is surrounded by an insulation film such as the silicon oxide film 51 within the semiconductor substrate 50 made of poly-silicon.

Although it has been described with regard to the lateral IGBT 8 as an example, the lateral FWD 7 can be also formed by using the semiconductor substrate 50 having the similar structure.

### Other Embodiments

In each of the above described embodiments, the lateral FWD 7 and the lateral IGBT 8 are exemplarily described. Also in the lateral MOSFET, similarly, the resistance value of the SRFP can be set similar to the resistance value of the SRFP 21, 34 of the lateral FWD 7 and the lateral IGBT 8. Also in such a case, the switching loss and the damage to the elements can be reduced. Further, in each of the above described embodiments, the SOI substrate 11 is used as the semiconductor substrate. The SOI substrate 11 is used to so as to further withstand a high voltage. The present invention is adaptable to the case where a simple silicon substrate or other semiconductor substrates are used.

That is, the present invention is adaptable to a semiconductor device that is a lateral element with the SRFP and where a first electrode such as the cathode electrode 19 and the collector electrode 32 and a second electrode such as the anode electrode 20 and the emitter electrode 33 are formed on the surface of a semiconductor layer such as the active layer 11c formed in the semiconductor substrate such as the SOI substrate 11 and an electric current flows between the first electrode and the second electrode.

In the above described second embodiment, the example of varying the resistance value of the SRFP 21, 34 in the longitudinal direction has been described. Alternatively, the resistance value of the SRFP 21, 34 may be varied in the longitudinal direction by employing another structure.

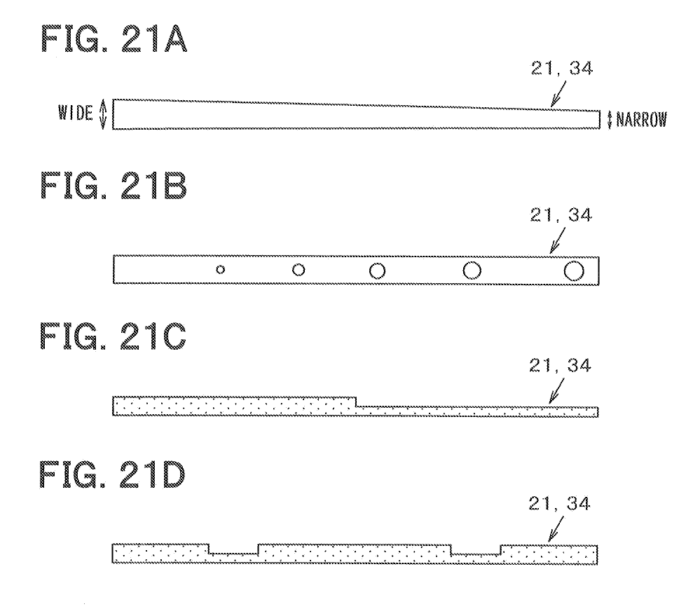

FIG. 21A and FIG. 21B are enlarged views illustrating other structures of a part of the SRFP 21, 34 formed in the lateral FWD 7 and the lateral IGBT 8, when viewed from the top. FIG. 21C and FIG. 21D are enlarged cross-sectional views illustrating other structures of a part of the SRFP 21, 34 formed in the lateral FWD 7 and the lateral IGBT 8.

As shown in FIG. 21A, the width of the SRFP 21, 34 can be gradually reduced in the longitudinal direction from the cathode or the collector toward the anode or the emitter. Such a structure can be realized by adjusting a mask pattern used when patterning the SRFP 21, 34.

As shown in FIG. 21B, holes are formed in the SRFP 21, 34 having the constant width in the longitudinal direction. The dimension of the holes is gradually increased from the cathode or the collector toward the anode or the emitter. Such a structure is also realized by adjusting a mask pattern used when patterning the SRFP 21, 34.

As shown in FIG. 21C, the SRFP 21, 34 has the constant width in the longitudinal direction, but the thickness of the SRFP 21, 34 can be gradually reduced from the cathode or the collector toward the anode or the emitter. Further, as shown in FIG. 21D, the SRFP 21, 34 has the constant width in the longitudinal direction, but is partly formed with the depressed portions. The number of the depressed portions can be increased from the cathode or the collector toward the anode or the emitter, and/or the length of the depressed portions can be increased from the cathode or the collector toward the anode or the emitter.

The structures shown in FIGS. 21C and 21D can be realized by etching through a mask for partly reducing the thickness of the SRFP 21, 34, in addition to the mask for patterning the SRFP 21, 34.

Further, the resistance value of the SRFP 21, 34 can be varied in the longitudinal direction by changing the material of the SRFP 21, 34. For example, the SRFP 21, 34 is made using different resistive materials such as doped Poly-Si and Cr—Si, and the material can be changed in the longitudinal direction. Also, the number of films of the different resistive materials can be changed with respect to the longitudinal direction. For example, a portion of the SRFP 21, 34 is made of a single film of doped Poly-Si and the remaining portion is made of two films of the doped Poly-Si and Cr—Si.

It has been described about the example of varying the resistance value of the SRFP 21, 34 per unit length with respect to the longitudinal direction in the case where the resistance value of the total resistance R of the SRFP 21, 34 is between 90 kΩ and 90 MΩ, preferably between 270 kΩ and 27 MΩ, and more preferably between 900 kΩ and 9 MΩ. However, it is possible to follow the change in voltage at the time of switching only by varying the resistance value per unit length of the SRFP 21, 34 in the longitudinal direction so that the resistance value per unit length increases from the cathode or the collector toward the anode or the emitter, and the effects of reducing the switching loss and the damage of the lateral element can be achieved.

Additional advantages and modifications will readily occur to those skilled in the art. The invention in its broader term is therefore not limited to the specific details, representative apparatus, and illustrative examples shown and described.

What is claimed is:

1. A semiconductor device comprising:
a semiconductor substrate having a first conductivity-type semiconductor layer;
a first electrode and a second electrode disposed on a surface of the semiconductor layer; and
a lateral element formed to flow an electric current between the first electrode and the second electrode, the semiconductor device further comprising:
a scroll-shaped resistive field plate disposed on the semiconductor layer across an insulation film, the scroll-shaped resistive field plate extending toward the second electrode while surrounding a periphery of the first electrode in a scroll shape, wherein a resistance value of a total resistance of the resistive field plate is in a range between 90 kΩ and 90 MΩ.

2. The semiconductor device according to claim 1, wherein the insulation film has a thickness of 200 nm to 1000 nm.

3. The semiconductor device according to claim 1, wherein a thickness of the insulation film is 0.42 μm, and the resistance value of the total resistance of the resistive field plate is in a range between 270 kΩ and 9 MΩ.

4. The semiconductor device according to claim 1, wherein a thickness of the insulation film is 0.42 μm, and the resistance value of the total resistance of the resistive field plate is in a range between 900 kΩ and 2.7 MΩ.

5. The semiconductor device according to claim 1, wherein a resistance value per unit length of the resistive field plate is constant with respect to a longitudinal direction thereof.

6. The semiconductor device according to claim 1, wherein a resistance value per unit length of the resistive field plate varies with respect to a longitudinal direction thereof.

7. The semiconductor device according to claim 6, wherein the resistance value per unit length of the resistive field plate increases from the first electrode to the second electrode.

8. A semiconductor device comprising:
a semiconductor substrate having a first conductivity-type semiconductor layer;
a first electrode and a second electrode disposed on a surface of the semiconductor layer; and
a lateral element formed to flow an electric current between the first electrode and the second electrode, the semiconductor device further comprising:
a scroll-shaped resistive field plate extending toward the second electrode while surrounding a periphery of the first electrode in a scroll shape, wherein a resistance value per unit length of the resistive field plate increases from the first electrode toward the second electrode.
